(19) United States
(12) Patent Application Publication
(10) Pub. No.: US 2009/0065934 A1
(43) Pub. Date: Mar. 12, 2009

(54) Wiring substrate, tape package having the same, display device having the tape package, method of manufacturing the wiring substrate, method of manufacturing a tape package having the same and method of manufacturing a display device having the tape package

(75) Inventors: Ye-Chung Chung, Suwon-si (KR); Don-Han Kim, Osan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/232,099

(22) Filed: Sep. 10, 2008

(30) Foreign Application Priority Data
Sep. 11, 2007 (KR) 10-2007-0091955

(51) Int. Cl. H01L 23/485; H01L 21/60; H05K 1/02; H05K 3/00

(52) U.S. Cl. 257/737; 361/749; 29/846; 438/118; 257/E23.019; 257/E21.511

(57) ABSTRACT

A wiring substrate may include a base film, a plurality of wires, a first insulation member and a second insulation member. The base film may have a chip-mounting region where a semiconductor chip may be mounted thereon. The wires may extend from the chip-mounting region and the wires may include adhesive end portions that may be electrically connected to the semiconductor chip. The first insulation member may cover portions of the wires outside the chip-mounting region thereof. The second insulation member may cover portions of the wire inside the chip-mounting region, the adhesive end portion of the wire being exposed by the second insulation member.

### PRIORITY STATEMENT

This application claims priority under 35 U.S.C. §119 to Korean Patent Application No. 2007-91955, filed on Sep. 11, 2007, in the Korean Intellectual Property Office (KIPO), the entire contents of which are herein incorporated by reference.

### BACKGROUND

1. Field

Example embodiments relate to a wiring substrate, a tape package including the wiring substrate, a display device including the tape package, a method of manufacturing the wiring substrate, a method of manufacturing a tape package including the wiring substrate, and a method of manufacturing a display device including the tape package.

2. Description of the Related Art

There are at least four processes used in manufacturing semiconductor devices. The first process is a fabrication process in which electric circuits (including electric elements) are formed on a semiconductor substrate, e.g., a silicon wafer. The second process is an electrical die sorting (EDS) process for inspecting electrical properties of chips formed by the fabrication process. The third process is a packaging process for sealing the chips with resin, e.g., epoxy. The fourth process is a sorting process for sorting the chips.

Semiconductor chips may be electrically connected to a substrate by various methods. For example, methods of electrically connecting the semiconductor chip to a substrate may include a wire bonding process, a solder bonding process, and a tape automated bonding (TAB) process. A semiconductor device, e.g., a semiconductor chip electrically connected to a substrate, and/or a semiconductor chip may be sealed with a resin during the packaging process. The resin may protect the semiconductor device and/or chip from the environment. The semiconductor package including the semiconductor chip mounted on a substrate may dissipate heat from the semiconductor chip to the outside through cooling functions thereof.

A tape package is a semiconductor package using a tape substrate. The tape package may be classified as either a tape carrier package (TCP) or a chip-on-film (COF) package. The manufacturing industry for tape packages, which may be used as driver integrated circuit (IC) components for flat-panel displays (FPDs), owes its growth to the development of the manufacturing industry for FPDs, e.g., liquid crystal displays (LCDs).

The TCP may have a structure where the semiconductor chip is bonded to an inner lead that is exposed through a window of the tape substrate by an inner lead bonding (ILB) process. The COF package may have a structure where the semiconductor chip is mounted on the tape substrate having no window by a flip-chip bonding process.

Input/output (I/O) wire patterns may be formed on the tape substrate and may be used as external connection terminals in the TAB process. The I/O wire patterns may be directly adhered to a printed circuit board (PCB) or a display panel to manufacture the tape package. For example, the semiconductor chip of the COF package may be mounted on a base film. In this example, bumps may be formed in a peripheral region of the semiconductor chip and the semiconductor chip may be mounted on the base film via the bumps by the flip-chip bonding process.

I/O wires may be formed on a base film. The I/O wires may include an adhesive end portion that may be adhered to bumps on a semiconductor chip. A solder resist may be coated on the base film outside a chip-mounting region where the semiconductor chip may be mounted thereon to protect the I/O wires from the outside. Alternatively, the semiconductor chip may be mounted on the chip-mounting region that may be exposed by a solder resist. The wire pattern of the tape package may be required to have a finer pitch as FPDs become miniaturized, slimmer and lightweight. Thus, pitches between the bumps of the semiconductor chip and between the I/O wires are being reduced.

However, in a conventional COF package, alignment errors between the bumps and the I/O wires, which are adhered to each other, may occur in the chip-mounting region due to the fine pitches. Shorts between adjacent I/O wires or between the bumps and the I/O wires may occur. Further, failures during the manufacturing process may be caused by foreign matter between the adjacent I/O wires or between the bump and the I/O wire.

### SUMMARY

Example embodiments provide a wiring substrate, a tape package including the wiring substrate, and a display device including the tape package. Example embodiments also provide for methods of manufacturing the wiring substrate, the tape package, and the display device.

According to example embodiments, a wiring substrate may include a base film including a chip-mounting region, the chip-mounting region configured for mounting a semiconductor chip thereon. The wiring substrate may also include a plurality of wires extending from the chip-mounting region. The wires may include adhesive end portions configured to electrically connect to a semiconductor chip. According to example embodiments, a wiring substrate may also include a first insulation member covering portions of the wires outside the chip-mounting region, and a second insulation member covering portions of the wires inside the chip-mounting region. According to example embodiments, the adhesive end portions of the wires may be exposed by the second insulation member. Example embodiments also provide for a tape package wherein the tape package includes a semiconductor chip mounted on the above described wiring substrate. Example embodiments also provide for a display device, wherein the display device includes the above described tape package, a printed circuit board, and a display panel.

According to example embodiments, a method of manufacturing a wiring substrate may include preparing a base film with a chip-mounting region, the chip-mounting region configured for mounting a semiconductor chip thereon. According to example embodiments, a method of manufacturing a wiring substrate may also include forming a plurality of wires extending from the chip-mounting region on the base film. The wires may include adhesive end portions configured to electrically connect to a semiconductor chip that may be mounted in the chip-mounting region. According to example embodiments, a method of manufacturing a wiring substrate may also include coating a first insulation member on portions of the wires outside the chip-mounting region thereof and coating a second insulation member on portions of the wires inside the chip-mounting region. According to example embodiments, the adhesive end portions of the wires may be exposed by the second insulation member. Example embodiments also provide for a method of manufacturing a tape package using the wiring substrate and a method of manufacturing a display device using the tape package.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a plan view illustrating a wiring substrate in accordance with example embodiments.

FIG. 2 is a plan view illustrating a semiconductor chip mounted on the wiring substrate in FIG. 1.

FIG. 3 is a partially enlarged view illustrating a portion “A” in FIG. 1.

FIG. 4 is a partially enlarged view illustrating a portion “A” in FIG. 1 in accordance with example embodiments.

FIG. 5 is a plan view illustrating a tape package including a semiconductor chip mounted on the wiring substrate in FIG. 1.

FIG. 6 is a partially enlarged view illustrating a portion “B” in FIG. 5.

FIG. 7 is a cross-sectional view illustrating a line VII-VII′ of FIG. 6.

FIG. 8 is a partially enlarged view illustrating a portion “B” in FIG. 5 in accordance with example embodiments.

FIG. 9 is a partially enlarged view illustrating a portion “B” in FIG. 5 in accordance with example embodiments.

FIG. 10 is a plan view illustrating a display device including the tape package in FIG. 5.

FIGS. 11 to 14 are plan views illustrating a method of manufacturing the tape package in FIG. 5.

### DETAILED DESCRIPTION OF EXAMPLE EMBODIMENTS

Various example embodiments will be described more fully hereinafter with reference to the accompanying drawings, in which some example embodiments are shown. Example embodiments may, however, be embodied in many different forms and should not be construed as limited to example embodiments set forth herein. Rather, example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, example embodiments will be explained in detail with reference to the accompanying drawings.

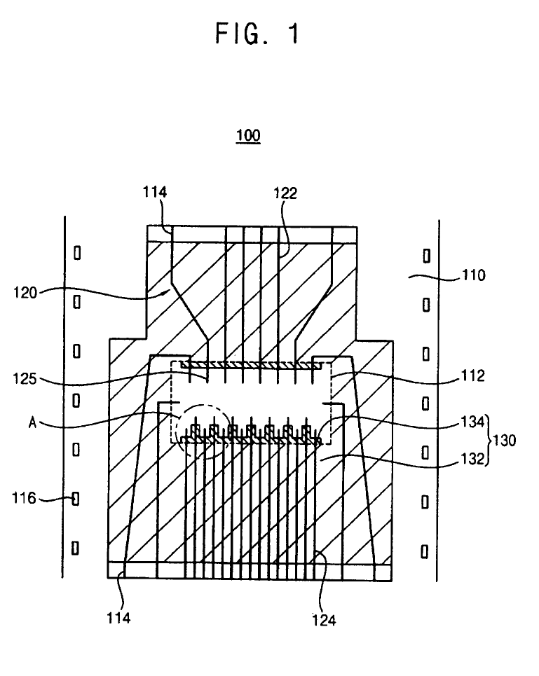

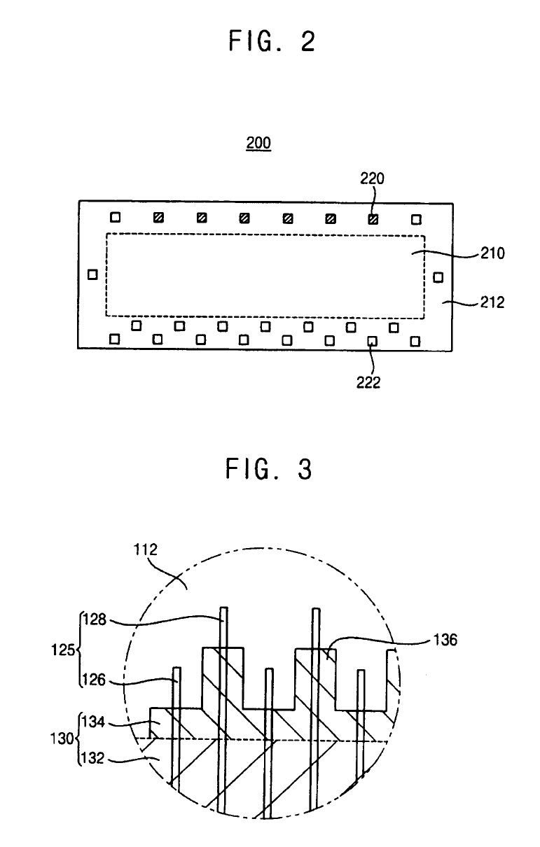

FIG. 1 is a plan view illustrating a wiring substrate in accordance with example embodiments. FIG. 2 is a plan view illustrating a semiconductor chip mounted on the wiring substrate in FIG. 1. Referring to FIGS. 1 and 2, a wiring substrate 100, upon which a semiconductor chip 200 may be mounted, may include a base film 110, a plurality of wires 120 formed on the base film 110 and an insulation member 130 coated on the wires 120.

In example embodiments, a chip-mounting region 112, where a semiconductor chip 200 may be mounted, may be provided in the middle of the base film 110. Sprocket holes 116 may be positioned along two opposite edges of the base film 110. The sprocket holes 116 may be spaced apart from one another.

According to example embodiments, a semiconductor chip 200 may include a middle portion 210 where integrated circuits (ICs) may be formed and a peripheral portion 212 where input pads 220 and output pads 222 may be formed. The input pad 220 and the output pad 222 may include bumps for electrical connections to the wires 120 formed on the base film 110.

In example embodiments, the number of the output pads 222 may be greater than the number of the input pads 220. The input pads 220 may be formed in a side region of the peripheral portion 212. The output pads 222 may be formed in the peripheral portion 212 except the side region where the input pads 220 are formed.

A plurality of the wires 120 may be formed on the base film 110. The wires 120 may extend from the inside to the outside of the chip-mounting region 112. In example embodiments, the wires 120 may include input wires 122 and output wires 124. The input wires 122 may extend in a first direction (upwardly) from the chip-mounting region 112. The output wires 124 may extend in a second direction (downwardly) opposite to the first direction from the chip-mounting region 112.

For example, the input wires 122 may extend in the first direction from the inside to the outside of the chip-mounting region 112. A printed circuit board (PCB) (not illustrated) may be provided to provide an input signal to the semiconductor chip 200, provided the semiconductor chip 200 is mounted on the chip-mounting region 112. The printed circuit board (PCB) may be electrically connected by the input wires 122 to the semiconductor chip 200 provided the semiconductor chip 200 is mounted on the chip-mounting region 122.

The output wires 124 may extend in the second direction from the inside to the outside of the chip-mounting region 112. A display panel (not illustrated) may receive an output signal from the semiconductor chip 200, provided the semiconductor chip 200 is mounted on the chip mounted region 112. The display panel may be electrically connected by the output wires 124 to the semiconductor chip 200 provided the semiconductor chip 200 is mounted on the chip-mounting region 122.

The wires 120 may include an adhesive end portion 125 that may be adhered to a bump of the semiconductor chip 200. The adhesive end portions 125 of the wires 120 may be positioned within the chip-mounting region 112 corresponding to the bumps of the semiconductor chip 200. Accordingly, the adhesive end portions 125 of the wires 120 may be adhered to the bumps of the semiconductor chip 200 and may be electrically connected to the semiconductor chip 200.

The arrangement of the input and output pads 220 and 222 of the semiconductor chip 200 is not to be construed as limiting thereof, and various arrangements thereof are possible. Also, the arrangement of the input and output wires 122 and 124 to be electrically connected to the input and output pads 220 and 222 may be arranged in many different forms, and is not to be construed as limited to the above-mentioned example embodiments.

In example embodiments, the insulation member 130 may be coated on the wires 120. The insulation member 130 may include a first insulation member 132 and a second insulation member 134. The first insulation member 132 may cover portions of the wires 120 outside the chip-mounting region 112, except portions 114 that may be connected to an external device, for example, a PCB or the display panel. The portions 114 that may be connected to the external device are exposed by the first insulation member 132. The second insulation member 134 may cover portions of the wires 120 inside the chip-mounting region 112, except the adhesive end portions 125 that may be connected to the bumps of the semiconductor chip 200. The adhesive end portions 125 that may be connected to the bumps of the semiconductor chip 200 may be exposed by the second insulation member 132. For example, the insulation member 130 may include a solder resist.

The first insulation member 132 may cover portions of the wires 120 outside the chip-mounting region 112. Accordingly, the portions of the wires 120 outside the chip-mounting region 112 may be protected from the outside by the first insulation member 132. The second insulation member 132 may cover portions of the wires 120 inside the chip-mounting region 112 except the adhesive end portions 125. The adhesive end portion 125 of each of the wires 120 may be exposed by the second insulation member 132. Accordingly, the adhesive end portions 125 to be adhered to the bump of the semiconductor chip 200 may be exposed by the second insulation member 132.

Therefore, the wires 120 in the chip-mounting region 122 may be prevented or retarded from shorting each other by the second insulation member 134. Although there is foreign matter between each of the wires 120 and the bump of the semiconductor chip 200, the second member 134 may protect the wires 120 from the foreign matter to prevent or reduce a failure in a following process.

For example, the first insulation member 132 and the second insulation member 134 may be simultaneously formed in the same process. The first insulation member 132 and the second insulation member 134 may be continuously formed to be connected to each other. Alternatively, the first insulation member 132 and the second insulation member 134 may be formed in different processes. In example embodiments, the second insulation member 134 formed inside the chip-mounting region 112 may be spaced apart from the first insulation member 132. Thus, the second insulation member 134 may be separated from the first insulation member 132 to cover the portions of the wires 120 inside the chip-mounting region 112.

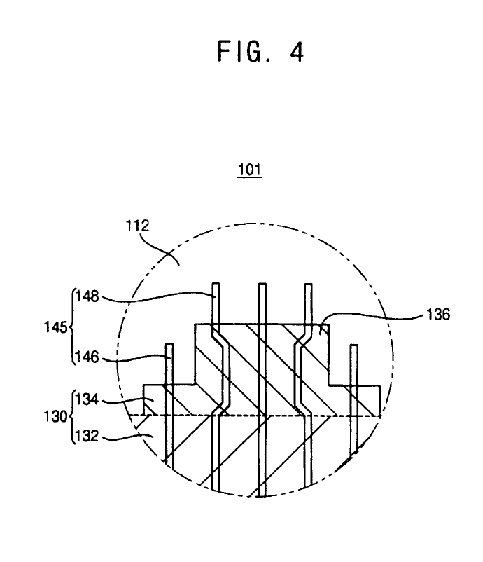

FIG. 3 is a partially enlarged view illustrating a portion “A” in FIG. 1. Referring to FIG. 3, the adhesive end portions 125 inside the chip-mounting region 112 may be alternately arranged in a zigzag shape. For example, the adhesive end portions 125 may include first end portions 126 and second end portions 128. The first end portions 126 may be arranged in a first line near a side edge of the chip-mounting region 112. The second end portions 128 may be arranged in a second line parallel with the first line.

The first insulation member 132 may cover portions of the wires 120 outside the chip-mounting region 112. The second insulation member 132 may cover portions of the wires 120 inside the chip-mounting region 112 except the adhesive end portions 125. The adhesive end portion 125 of each of the wires 120 may be exposed by the second insulation member 134.

The second insulation member 134 coated inside the chip-mounting region 112 may include a protruding portion 136. The protruding portion 136 of the second insulation member 134 may cover portions of each of the wires 120 arranged to protrude through or from the side edge of the chip-mounting region 112.

The bumps of the semiconductor chip 200 may be adhered to the first and second end portions 126 and 128 that may be alternately arranged in a zigzag shape. The wires 120 may be arranged densely to have fine pitches therebetween in response to the increased channels of the semiconductor chip 200. Pitch, P, as used in this description and illustrated in FIG. 3, relates to the distance between the centers of adjacent wires.

Referring to FIGS. 1 and 3, the output wires 124 inside the chip-mounting region 112 may be alternately arranged in a zigzag shape. Similarly, the input wires 122 inside the chip-mounting region 112 may be alternately arranged in a zigzag shape. Accordingly, the input and output wires 122 and 124 may be arranged densely in response to the increased channels of the semiconductor chip 200.

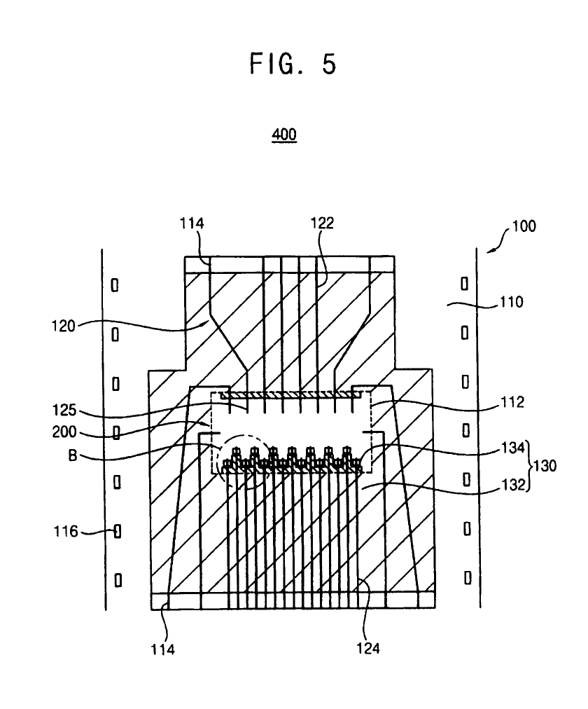

FIG. 4 is a partially enlarged view illustrating a portion “A” in FIG. 1 in accordance with example embodiments. The wiring substrate, as illustrated in FIG. 4, may be substantially the same as the wiring substrate illustrated in FIG. 1, except for an arrangement of the adhesive end portions. Thus, the same reference numerals will be used to refer to the same or similar parts as those described in FIG. 1, and any further explanation concerning the above elements will be omitted.

Referring to FIG. 4, a wiring substrate 101 according to example embodiments may include adhesive end portions 145 that may be alternately arranged in a zigzag shape. The adhesive end portions 145 may include first end portions 146 and second end portions 148. The first end portions 126 may be arranged in a first line adjacent to a side edge of the chip-mounting region 112. The second end portions 128 may be arranged in a second line parallel with the first line.

In example embodiments, at least two second end portions 148 may be disposed between two first end portions 146. For example, three second end portions 148 may be disposed between two first end portions 146.

The second insulation member 134 may be coated inside the chip-mounting region 112 and may include a protruding portion 136. The protruding portion 136 of the second insulation member 134 may cover portions of each of the wires 120 arranged to protrude through or from the side edge of the chip-mounting region 112. Accordingly, although the adhesive end portions 145 having various arrangements may be densely arranged, the second insulation member 134 may prevent or retard the wires 120 in the chip-mounting region 122 from shorting each other, to thereby provide the wires 120 having finer pitches therebetween.

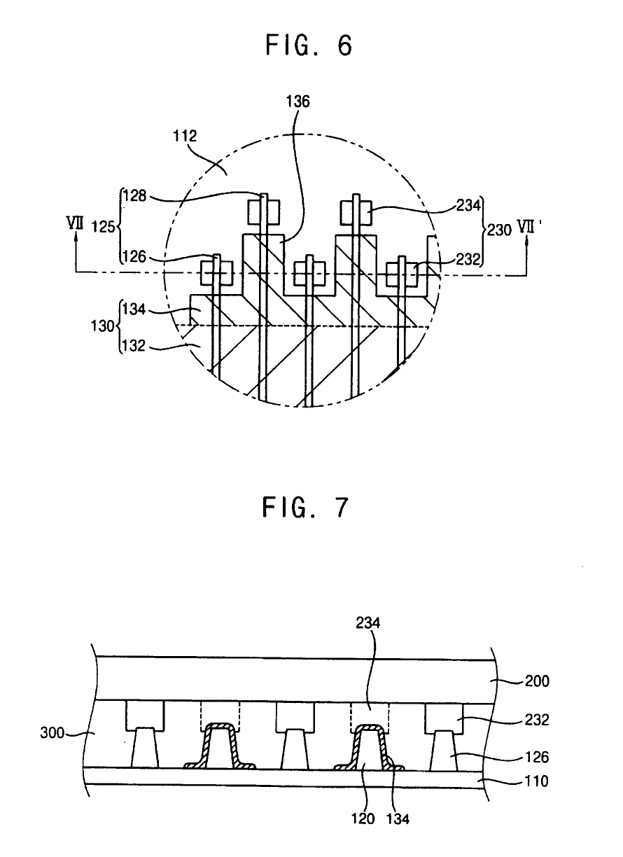

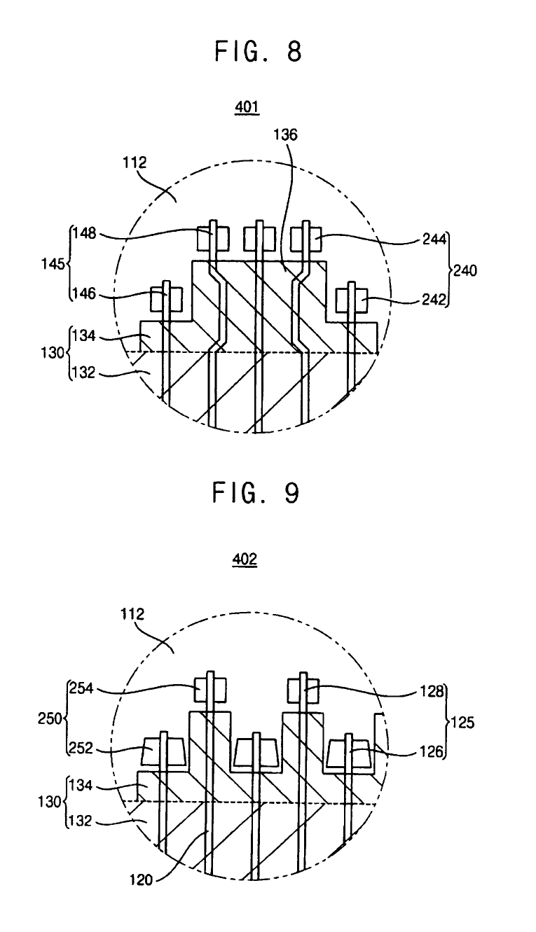

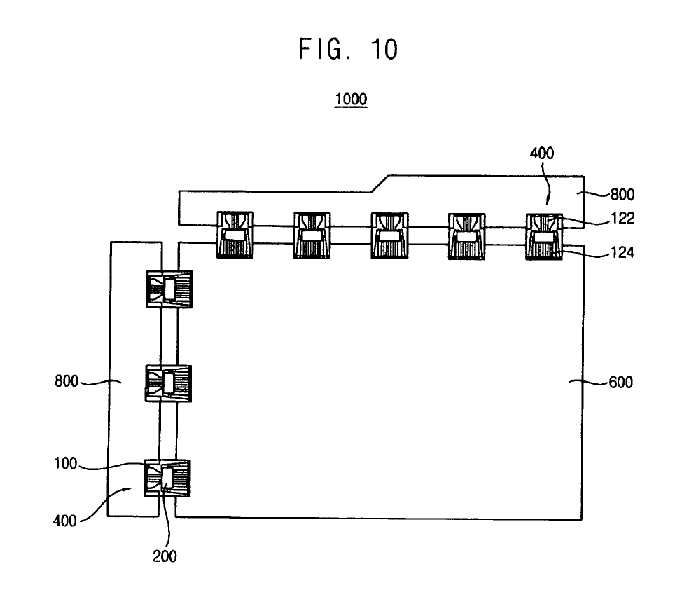

FIG. 5 is a plan view illustrating a tape package. In accordance with example embodiments, a tape package 400 may include a semiconductor chip 200 mounted on the wiring substrate in FIG. 1. FIG. 6 is a partially enlarged view illustrating a portion “B” in FIG. 5. FIG. 7 is a cross-sectional view illustrating a line VII-VII′ of FIG. 6. Referring FIGS. 5 to 7, a tape package 400 may include a base film 110, a plurality of wires 120 formed on the base film 110, an insulation member 130 coated on the wires 120 and a semiconductor chip 200 mounted on the base film 110.

The base film 110 of the wiring substrate 100 may include a chip-mounting region 112 where the semiconductor chip 200 is mounted. A plurality wires 120 may extend from the inside to the outside of the chip-mounting region 112. As shown in FIG. 5, the semiconductor chip 200 may be mounted on the chip-mounting region 112 of the base film 110.

The semiconductor chip 200 may include input pads 220 and output pads 222. The input pad 220 and the output pad 222 of the semiconductor chip 200 may include bumps 230, respectively. The bumps 230 of the semiconductor chip 200 may be adhered to adhesive end portions 125 that may be positioned on end portions of the wires 120. For example, the bumps 230 may be adhered to the adhesive end portions 125 by a flip-chip bonding process.

The wires 120 may be coated with the insulation member 130. The insulation member 130 may include a first insulation member 132 and a second insulation member 134. The first insulation member 132 may cover portions of the wires 120 outside the chip-mounting region 112. The second insulation member 134 may cover portions of the wires 120 inside the chip-mounting region 112, except the adhesive end portions 125. The adhesive end portion 125 of each of the wires 120 may be exposed by the second insulation member 132. Accordingly, the adhesive end portion 125 may be exposed by the second insulation member 134 to be adhered to the bump 230 of the semiconductor chip 200.

The semiconductor chip 200 may be mounted on the base film 110 via the bumps 230. In example embodiments, a plastic resin 300 may fill a space where the semiconductor chip 200 is bonded to the base film 110. For example, the portion where the semiconductor chip 200 is bonded to the base film 110 may be filled with the plastic resin 300 through an underfill process.

In example embodiments, the bumps 230 of the semiconductor chip 200 may be alternately arranged in a zigzag shape. The adhesive end portions 125 may be alternately arranged in a zigzag shape corresponding to the bumps 230. For example, the bumps 230 may include first bumps 232 and second bumps 234. The first bumps 232 may be arranged in a first line near a side edge of the semiconductor chip 200. The second bumps 234 may be arranged in a second line parallel with the first line. Similarly, the adhesive end portions 125 may include first end portions 126 and second end portions 128. The first end portions 126 may be arranged in a first line adjacent to a side edge of the chip-mounting region 112. The second end portions 128 may be arranged in a second line parallel with the first line.

The second insulation member 134 may be coated inside the chip-mounting region 112 and may include a protruding portion 136. The protruding portion 136 of the second insulation member 134 may cover portions of each of the wires 120 arranged to protrude through or from the side edge of the chip-mounting region 112.

FIG. 7 is a cross-sectional view taken along the first line in FIG. 6. Referring again to FIG. 7, the first bumps 232 may be arranged in the first line and may be adhered to the first end portions 126 of the wires 120 on the base film 110. The second bumps 234 (illustrated with dotted lines in FIG. 7) may be arranged in the second line parallel with the first line.

As illustrated in the figures, each of the first bumps 232 adhered to the first end portion 126 may be positioned near each of the wires 120 including the second end portion 128. Each of the wires 120 near each of the first bumps 232 may be coated with the second insulation member 134. Accordingly, the second insulation member 134 may prevent or reduce a failure due to foreign matter between each of the first bumps 232 and each of the wires 120 adjacent to each of the first bumps 232. The second insulation member 134 may also prevent or reduce the wires 120 from shorting each other, to thereby provide the wires 120 having finer pitches therebetween.

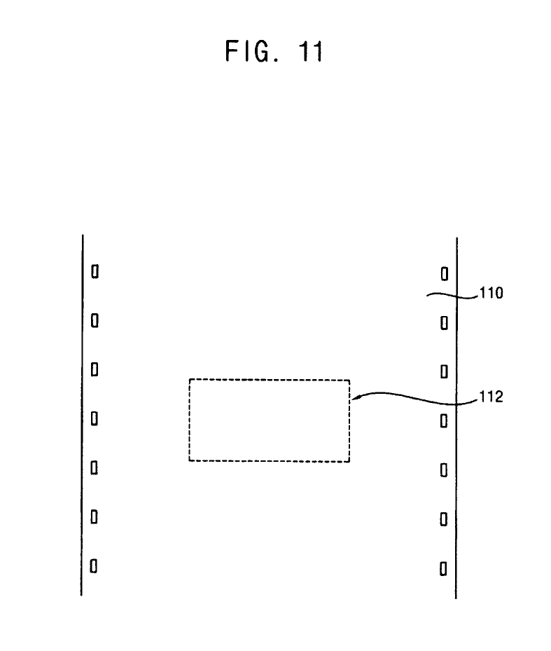

FIG. 8 is a partially enlarged view illustrating a portion “B” in FIG. 5 in accordance with example embodiments. The tape package illustrated in FIG. 8 may be substantially the same the tape package illustrated in FIG. 5, except for an arrangement of the bumps and the adhesive end portions. Thus, the same reference numerals will be used to refer to the same or similar parts as those described in the embodiment of FIG. 5, and any further explanation concerning the above elements will be omitted.

Referring to FIG. 8, a tape package 401 in accordance with example embodiments may include bumps 240 and adhesive end portions 145 that may be alternately arranged in a zigzag shape. For example, the bumps 240 may include first bumps 242 and second bumps 244. The first bumps 242 may be arranged in a first line near a side edge of the semiconductor chip 200. The second bumps 244 may be arranged in a second line parallel with the first line. Similarly, the adhesive end portions 145 may include first end portions 146 and second end portions 148. The first end portions 146 may be arranged in a first line near a side edge of the chip-mounting region 112. The second end portions 148 may be arranged in a second line parallel with the first line.

At least two second end portions 148 may be arranged between two first end portions 146. For example, three second end portions 148 may be arranged between two first end portions 146. Each of the first bumps 242 may be adhered to the first end portion 146 and each of the second bumps 244 may be adhered to the second end portion 148. The second insulation member 134 coated inside the chip-mounting region 112 may include a protruding portion 136. The protruding portion 136 of the second insulation member 134 may cover portions of each of the wires 120 arranged to protrude through or from the side edge of the chip-mounting region 112.

Accordingly, although the adhesive end portions 145 having various arrangements may be densely arranged, the second insulation member 134 may prevent or reduce the wires 120 in the chip-mounting region 122 from shorting each other, and may provide the wires 120 with finer pitches therebetween.

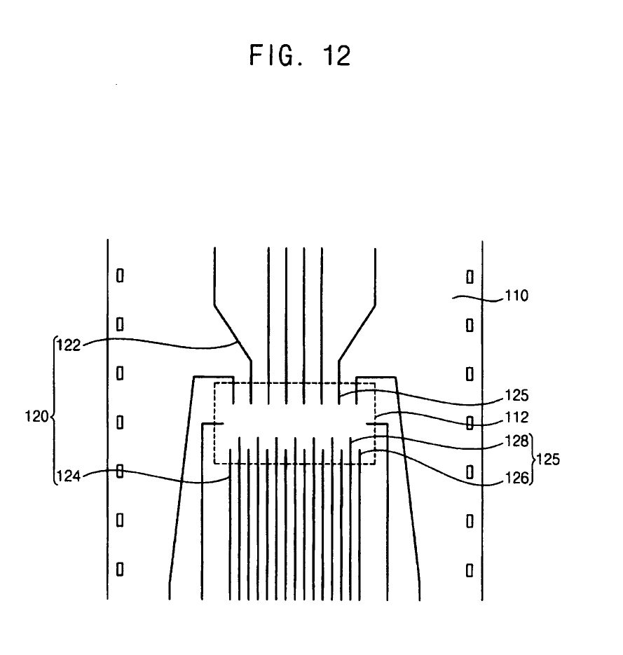

FIG. 9 is a partially enlarged view illustrating a portion “B” in FIG. 5 in accordance with example embodiments. The tape package illustrated in FIG. 9 may be substantially the same as the tape package illustrated in FIG. 5, except for sizes of the bumps. Thus, the same reference numerals will be used to refer to the same or similar parts as those described in FIG. 5, and any further explanation concerning the above elements will be omitted.

Referring to FIG. 9, a tape package 402 in accordance with example embodiments may include bumps 250 and adhesive end portions 125 that are alternately arranged in a zigzag shape. For example, the bumps 250 may include first bumps 252 and second bumps 254. The first bumps 252 may be arranged in a first line near a side edge of the semiconductor chip 200. The second bumps 254 may be arranged in a second line parallel with the first line. Similarly, the adhesive end portions 125 may include first end portions 126 and second end portions 128. The first end portions 126 may be arranged in a first line near a side edge of the chip-mounting region 112. The second end portions 128 may be arranged in a second line parallel with the first line.

The first bumps 252 may have a first size and the second bumps 254 may have a second size smaller than the first size. Although the size of the first bumps 252 is greater than that of the second bumps 254, the second insulation member 134 may prevent or retard the first bumps 252 and the wires 120 near the first bumps 252 from shorting each other. Further, although the wires 120 may have finer pitches, alignment errors between the bumps 250 and the wires 120 may be prevented or reduced because the bump 250 may be formed to have a relatively large size.

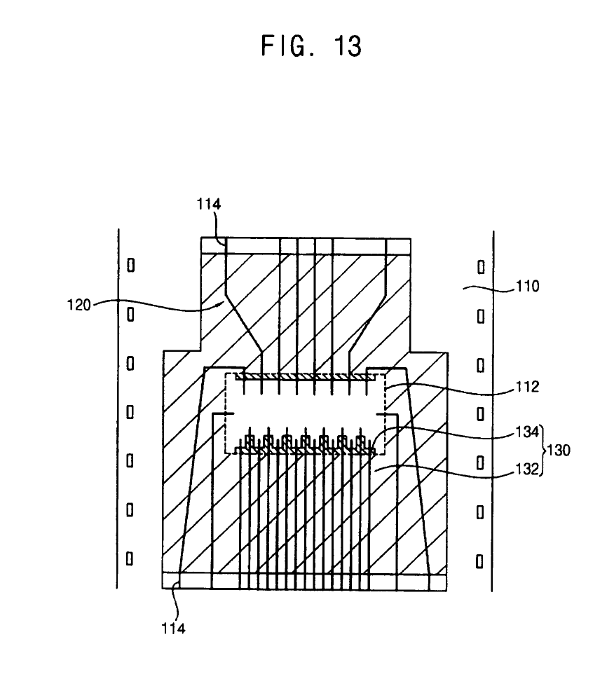

FIG. 10 is a plan view of a display device that may include a tape package substantially the same as the tape package illustrated in FIG. 5. Thus, the same reference numerals will be used to refer to the same or similar parts as those described in example embodiments illustrated in FIG. 5, and any further explanation concerning the above elements will be omitted.

Referring to FIG. 10, a display device 1000 in accordance with example embodiments may include a tape package 400, a display panel 600 and a PCB 800. The tape package 400 may be disposed between the display panel 600 and the PCB 800. The PCB 800 may be disposed in a first side portion of the tape package 400. The display panel 600 may be disposed in a second side portion opposite to the first side portion of the tape package 400.

The tape package 400 may include input wires 122 and the input wires 122 may be electrically connected to the PCB 800. The tape package 400 may also include output wires 124 and the output wires 124 may be electrically connected to the display panel 600. For example, the display panel 600 may include a plurality of gate lines, a plurality of data lines and a plurality of pixels. The pixels may be formed on each intersection of the gate lines and the date lines. The pixel may include a thin-film transistor (TFT) having a gate electrode connected to the gate line and a source electrode connected to the data line.

The semiconductor chip 200 mounted on the tape package 400 may include driving circuits for driving the display panel 600. For example, the semiconductor chip 200 of the tape package 400 may combine with a first side of the display panel 600 and may include a gate driver for driving the gate lines of the display panel 600. The semiconductor chip 200 of the tape package 400 that combines with a second side substantially perpendicular to the first side of the display panel 600 may include a data driver for driving the data lines of the display panel 600.

The PCB 800 may be electrically connected to the input wires 122 of the tape package 400. For example, the PCB 800 may include a timing controller (not illustrated) and a power supply (not illustrated). The timing controller may control a driving timing of the gate driver and the data driver. The power supply may provide power required for the driving circuits of the display panel 600 and the semiconductor chip 200 that is mounted on the tape package 400.

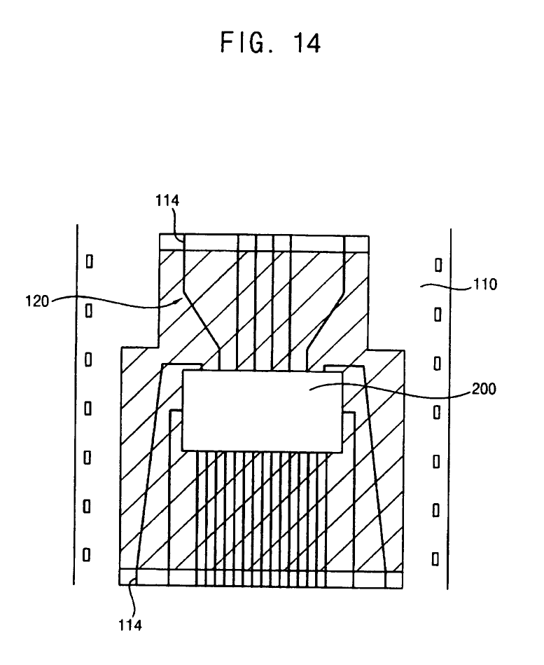

Hereinafter, a method of manufacturing the above-mentioned tape package will be described. FIGS. 11 to 14 are plan views illustrating a method of manufacturing the tape package in FIG. 5. Referring to FIG. 11, a base film 110 may be prepared for mounting a semiconductor chip thereon. A chip-mounting region 112, where the semiconductor chip 200 is mounted, may be provided in the middle of the base film 110. The base film may be a flexible organic film, however, example embodiments are not limited thereto.

Referring to FIG. 12, a plurality of the wires 120 may be formed on the base film 110. The wires 120 may be formed to extend from the chip-mounting region 112. The wires 120 may extend from the inside to the outside of the chip-mounting region 112. An end portion of each of the wires 120 may include an adhesive end portion 125. The adhesive end portion 125 may be positioned inside the chip-mounting region 112 and may be configured to electrically connect to a semiconductor chip mounted thereon.

In example embodiments, the wires 120 may include input wires 122 and output wires 124. The input wires 122 and the output wires 124 may be formed on the base film 110. The input wires 122 may extend in a first direction (upwardly) from the chip-mounting region 112. The output wires 124 may extend in a second direction (downwardly) opposite to the first direction from the chip-mounting region 112.

In an example embodiment, the adhesive end portions 125 may be inside the chip-mounting region 112 and may be alternately arranged in a zigzag shape. For example, the adhesive end portions 125 may include first end portions 126 and second end portions 128. The first end portions 126 may be arranged in a first line near a side edge of the chip-mounting region 112. The second end portions 128 may be arranged in a second line parallel with the first line.

For example, a metal thin film may be adhered to a surface of the base film 110 by an electrodeposition or thermocompression process and a photolithography process and an etch process may be performed on the metal thin film to form the wires 120. Examples of the metal may be copper (Cu), gold (Au), tin (Sn), lead (Pb), silver (Ag), and nickel (Ni); however, example embodiments are not limited thereto. Additionally, other conductive material may be formed on the wires 120 by an electroplating process.

Referring to FIG. 13, the insulation member 130 may be coated on the wires 120. An insulation member 130 may be coated on portions of the wires 120 except portions (the adhesive end portion 125 of the wires 120) that may be connected to bumps 230 (see FIG. 6) of the semiconductor chip 200 (see FIG. 14) and portions 114 of the wires 200 that may be connected to an external device, for example, a PCB or a display panel, to insulate the wires 200. The insulation member 130 may include a first insulation member 132 and a second insulation member 134.

A first insulation member 132 and a second insulation member 134 may be coated on the wires 120. The first insulation member 132 may cover the portions of the wires 120 outside the chip-mounting region 112, except the portions 114 of the wires 120 that may be connected to the external device. The second insulation member 134 may cover the portions of the wires 120 inside the chip-mounting region 112, except the adhesive end portions 125. The insulation member 130 may include a solder resist.

In example embodiments, the second insulation member 134 may include a protruding portion 136. Portions of each of the wires 120 arranged to protrude from the side edge of the chip-mounting region 112 may be coated with the protruding portion 136 of the second insulation member 134. Therefore, because the wires 120 adhered to base film 110 may be coated with the insulation member 130 including the solder resist, a wire pattern having a pitch of about 40 μm or less may be formed without a failure, e.g., a short.

Referring to FIG. 14, the semiconductor chip 200 may be mounted on the base film 110. The bumps 230 of the semiconductor chip 200 may be adhered to the adhesive end portions 125 of the wires 120. Referring again to FIGS. 2 and 6, input and output pads 220 and 222 of the semiconductor chip 200 may include bumps 230. The bumps 230 may be adhered to the adhesive end portions 125 of the wires 120 in the chip-mounting region 112. For example, the bump 230 may include gold (Au) and/or copper (Cu), however, example embodiments are not limited thereto.

In example embodiments, the bumps 230 of the semiconductor chip 200 may be adhered to the adhesive end portions 125 of each of the wires 120 by a flip-chip bonding process. For example, the base film 110 including the wires 120 formed thereon may be positioned on a stage of a thermocompression apparatus (not illustrated). After the stage is heated to about 100° C. and a press head (not illustrated) for pressing the semiconductor chip 200 on the base film 110 is heated to about 450° C., the semiconductor chip 200 may be thermally compressed to be mounted on the chip-mounting region 112.

In example embodiments, the bumps 230 may be alternately arranged in a zigzag shape in a peripheral region of the semiconductor chip 200 and the adhesive end portions 125 of the wires 120 may be arranged alternately in a zigzag shape corresponding to the bumps 230. For example, the bumps 230 may include first bumps 232 and second bumps 234. The first bumps 232 may be arranged in a first line adjacent to a side edge of the semiconductor chip 200. The second bumps 234 may be arranged in a second line parallel with the first line. Similarly, the adhesive end portions 125 may include first end portions 126 and second end portions 128. The first end portions 126 may be arranged in a first line near a side edge of the chip-mounting region 112. The second end portions 128 may be arranged in a second line parallel with the first line. The adhesive end portions 125 of the wires 120 may be alternately arranged in a zigzag shape corresponding to the bumps 230.

In example embodiments, at least two second end portions 148 of the adhesive end portions 145 may be arranged between two first end portions 146 of the adhesive end portions 145. For example, three second end portions 148 may be arranged between two first end portions 146. The adhesive end portions of the wires 145 may be arranged to the first and the second bumps 242 and 244 and may be adhered to the first and the second bumps 242 and 244, respectively.

In example embodiments, first and second bumps 252 and 254 may have different sizes corresponding to arrangements thereof. The first bumps 252 may have a first size and the second bumps 254 may have a second size smaller than the first size.

Referring again to FIG. 7, a plastic resin 300 may be injected into a bonded region of the base film 110 and the semiconductor chip 200. For example, the plastic resin 300 may be injected to the bonded region of the semiconductor chip 200 through an underfill process. Referring again to FIG. 10, a first end portion of the tape package 400 may be combined with the PCB 800 and a second end portion of the tape package 400 may be combined with the display panel 600.

Both edge side portions of the base film 110, where the sprocket holes 116 are formed, may be removed. The input wires 122 of the wires 120 of the tape package 400 may be electrically connected to the PCB 800 and the output wires 124 of the wires 120 of the tape package 400 may be electrically connected to the display panel 600. The display device 1000 may be completed by conventional processes for a flat-panel display (FPD) device.

As mentioned above, a wiring substrate in accordance with example embodiments may include a base film having a chip-mounting region where a semiconductor chip may be mounted thereon. The wiring substrate may further include a plurality of wires extending from the chip-mounting region on the base film. The wires may include an adhesive end portions that may be electrically connected to a semiconductor chip.

A first insulation member and a second insulation member may be coated on the base film. The first insulation member may cover portions of the wires outside the chip-mounting region thereof. The second insulation member may cover portions of the wires inside the chip-mounting region except the adhesive end portions.

Therefore, although the adhesive end portions having various arrangements are densely arranged inside the chip-mounting region, the second insulation member may prevent or reduce the wires in the chip-mounting region from shorting each other, to thereby provide wires having finer pitches therebetween.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the example embodiments disclosed, and that modifications to example embodiments are intended to be included within the scope of the appended claims.

What is claimed is:

1. A wiring substrate comprising:
a base film including a chip-mounting region, the chip-mounting region configured for mounting a semiconductor chip thereon;
a plurality of wires extending from inside the chip-mounting region to outside the chip mounting region, the wires including adhesive end portions inside the chip-mounting region, the adhesive end portions configured to electrically connect to a semiconductor chip;
a first insulation member covering portions of the wires outside the chip-mounting region; and
a second insulation member covering portions of the wires inside the chip-mounting region, the adhesive end portions of the wire being exposed by the second insulation member.

2. The wiring substrate of claim 1, wherein the adhesive end portions are arranged in a zigzag shape.

3. The wiring substrate of claim 2, wherein the adhesive end portions comprise:
two first end portions in a first line; and
at least two second end portions between the two first end portions, the at least two second end portions in a second line parallel with the first line.

4. The wiring substrate of claim 1, wherein the second insulation member includes a protruding portion for covering portions of the wires inside the chip-mounting region.

5. The wiring substrate of claim 1, wherein the plurality of wires comprise:
at least one input wire extending in a first direction from the chip-mounting region; and
at least one output wire extending in a second direction opposite to the first direction, the at least one output wire extending from the chip-mounting region.

6. A tape package comprising:
a semiconductor chip including bumps formed thereon; and
the wiring substrate of claim 1, wherein the semiconductor chip is mounted on the chip-mounting region and the adhesive end portions are adhered to the bumps of the semiconductor chip.

7. The tape package of claim 6, wherein the bumps are in a zigzag shape in a peripheral region of the semiconductor chip, and the adhesive end portions are in a zigzag shape corresponding to the bumps.

8. The tape package of claim 7, wherein the adhesive end portions comprise:
two first end portions in a first line; and
at least two second end portions between the two first end portions, the at least two second end portions in a second line parallel with the first line.

9. The tape package of claim 7, wherein the bumps comprise:
first bumps adhered to first end portions arranged in a first line, the first bumps having a first size; and
second bumps adhered to second end portions arranged in a second line parallel with the first line, the second bumps having a second size different than the first size.

10. The tape package of claim 7, wherein the second insulation member includes a protruding portion for covering a portion of the wires inside the chip-mounting region.

11. The tape package of claim 7, further comprising:
a plastic resin for protecting a bonded region of the base film and the semiconductor chip.

12. The tape package of claim 7, wherein the plurality of wires comprise:
input wires extending in a first direction from the chip-mounting region; and
output wires extending from the chip-mounting region in a second direction opposite to the first direction.

13. A display device comprising:
the tape package of claim 6, wherein the plurality of wires includes a plurality of input wires and a plurality of output wires;
a printed circuit board (PCB) in a first end portion of the tape package, the PCB being electrically connected to the input wires; and
a display panel in a second end portion of the tape package, the display panel being electrically connected to the output wires.

14. The display device of claim 13, wherein the bumps are in a zigzag shape in a peripheral region of the semiconductor chip, and the adhesive end portions are in a zigzag shape corresponding to the bumps.

15. The display device of claim 13, wherein the second insulation member includes a protruding portion for covering a portion of the input and output wires inside the chip-mounting region.

16. A method of manufacturing a wiring substrate, comprising:
preparing a base film with a chip-mounting region, the chip-mounting region configured for mounting a semiconductor chip thereon;
forming a plurality of wires extending from inside the chip-mounting region on the base film to outside the chip-mounting region, the wires including adhesive end portions inside the chip-mounting region configured to electrically connect to a semiconductor chip;
coating a first insulation member on portions of the wires outside the chip-mounting region thereof; and
coating a second insulation member on portions of the wires inside the chip-mounting region, the adhesive end portions of the wire being exposed by the second insulation member.

17. The method of claim 16, wherein forming the plurality of wires includes arranging the adhesive end portions in a zigzag pattern.

18. The method of claim 17, wherein forming the plurality of wires comprises:
arranging two first end portions in a first line; and
arranging at least two second end portions between the two first end portions in a second line parallel with the first line.

19. The method of claim 16, wherein coating a second insulation member on portions of the wires inside the chip-mounting region includes coating a protruding portion of the second insulation member on a portion of the wires inside the chip-mounting region.

20. The method of claim 16, wherein forming a plurality of wires comprises:
forming at least one input wire extending in a first direction from the chip-mounting region; and
forming at least one output wire extending in a second direction opposite to the first direction, the at least one output wire extending from the chip-mounting region.

21. A method of manufacturing a tape package, comprising:
manufacturing a wiring substrate according to claim 16;
providing a semiconductor chip, the semiconductor chip including bumps formed thereon; and
mounting the semiconductor chip on the chip-mounting region.

22. The method of claim 21, wherein the bumps are in a zigzag shape in a peripheral region of the semiconductor chip, and forming the plurality of wires includes arranging the adhesive end portions in a zigzag shape corresponding to the bumps.

23. The method of claim 22, wherein forming the plurality of wires comprises:
arranging two first end portions in a first line; and
arranging at least two second end portions between the two first end portions in a second line parallel with the first line.

24. The method of claim 22, wherein the bumps comprise:
first bumps configured to adhere to first end portions arranged in a first line, the first bumps having a first size; and
second bumps configured to adhere to second end portions arranged in a second line parallel with the first line, the second bumps having a second size different than the first size.

25. The method of claim 21, wherein coating a second insulation member on portions of the wires inside the chip-mounting region includes coating a protruding portion of the second insulation member on a portion of the wires inside the chip-mounting region.

26. The method of claim 21, wherein forming the plurality of wires comprise:
forming at least one input wire extending in a first direction from the chip-mounting region; and
forming at least one output wire extending in a second direction opposite to the first direction, the at least one output wire being formed to extend from the chip-mounting region.

27. The method of claim 21, wherein mounting the semiconductor chip includes adhering the bumps of the semiconductor chip to the adhesive end portions of the wires.

28. The method of claim 21, further comprising:
injecting a plastic resin to a bonded region of the base film and the semiconductor chip.

29. A method of manufacturing a display device, comprising:
manufacturing a tape package according to claim 21;
combining a first end portion of the tape package with a PCB; and
combining a second end portion of the tape package with a display panel.

30. The method of claim 29, wherein the bumps are in a zigzag shape in a peripheral region of the semiconductor chip, and forming the plurality of wires includes arranging the adhesive end portions in a zigzag shape corresponding to the bumps.

31. The method of claim 30, wherein forming the plurality of wires comprises:
arranging two first end portions in a first line; and
arranging at least two second end portions between the two first end portions in a second line parallel with the first line.

32. The method of claim 30, wherein the bumps comprise:
first bumps adhered to first end portions arranged in a first line, the first bumps having a first size; and
second bumps adhered to second end portions arranged in a second line parallel with the first line, the second bumps having a second size different than the first size.

33. The method of claim 29, wherein coating the second insulation member on portions of the wires inside the chip-mounting region includes coating a protruding portion of the second insulation member on a portion of the wires that is inside the chip-mounting region.

34. The method of claim 29, wherein forming a plurality of wires includes forming a plurality of input wires and a plurality of output wires and combining the first end portion of the tape package with the PCB includes electrically connecting the input wires to the PCB.

35. The method of claim 29, wherein forming the plurality of wires includes forming a plurality of input wires and a plurality of output wires and combining the second end portion of the tape package with a display panel includes electrically connecting the plurality of output wires to the display panel.
